(19) United States
(12) Patent Application Publication
(10) Pub. No.: US 2025/0342297 A1
(43) Pub. Date: Nov. 6, 2025

(54) SCHEDULING METHOD FOR DAILY ECOLOGICAL FLOW VARIATION OF RIVER REACH BASED ON FISH HABITAT SUITABILITY OVERLAP RATE

(71) Applicants: China Renewable Energy Engineering Institute, Beijing (CN); China Renewable Energy Engineering Institute Co., Ltd, Beijing (CN); China Water Resources and Hydropower Construction Engineering Consulting Co., Ltd, Beijing (CN)

(72) Inventors: Hongbin GU, Beijing (CN); Guoyong ZHANG, Beijing (CN); Zenghai ZHAO, Beijing (CN); Tao HE, Beijing (CN); Hao JIANG, Beijing (CN); Weiying WANG, Beijing (CN); Bo LU, Beijing (CN); Lianfang XUE, Beijing (CN)

(73) Assignees: China Renewable Energy Engineering Institute, Beijing (CN); China Renewable Energy Engineering Institute Co., Ltd, Beijing (CN); China Water Resources and Hydropower Construction Engineering Consulting Co., Ltd, Beijing (CN)

(21) Appl. No.: 19/268,839

(22) Filed: Jul. 14, 2025

Related U.S. Application Data
(63) Continuation of application No. PCT/CN2024/140789, filed on Dec. 20, 2024.

(30) Foreign Application Priority Data
Jan. 16, 2024 (CN) 202410061231.7

(51) Int. Cl. G06F 30/28

(52) U.S. Cl. CPC G06F 30/28

(57) ABSTRACT

A scheduling method for a daily ecological flow variation of a river reach based on an overlap rate of suitable habitats for fish, includes: drawing a baseline flow-scheduled flow increment-fish habitat suitability overlap rate distribution map; and acquiring a daily mean flow of a current day to serve as a baseline flow, searching the baseline flow-scheduled flow increment-fish habitat suitability overlap rate distribution map to obtain a range of scheduled flow increments with an overlap rate of suitable habitats for fish greater than a preset value, and in combination with the baseline flow and the range of the scheduled flow increments, obtaining a flow scheduling range for a next day. The present disclosure quantitatively evaluates the overlap rate of the suitable spawning region of the fish in different flow variations under different baseline flows, thereby obtaining a constraint value for the ecological flow variation of the river reach.

### CROSS-REFERENCE TO RELATED APPLICATIONS

This application is a continuation of International Patent Application No. PCT/CN2024/140789 with a filing date of Dec. 20, 2024, designating the United States, now pending, and further claims priority to Chinese Patent Application No. 202410061231.7 with a filing date of Jan. 16, 2024. The content of the aforementioned applications, including any intervening amendments thereto, is incorporated herein by reference.

### TECHNICAL FIELD

The present disclosure belongs to the technical field of flow scheduling, and in particular to a scheduling method for a daily ecological flow variation of a river reach based on an overlap rate of suitable habitats for fish.

### BACKGROUND

Fish are widely used as indicator species to evaluate and preserve the ecosystems of rivers. Their reproductive behaviors are significantly influenced by flow processes in river channels. Construction of hydropower stations can alter the natural flow processes of river channels, obstruct fish migration pathways, and disrupt fish habitats. Implementing ecological scheduling in the hydropower stations to control the release of appropriate ecological flows and meet the hydrodynamic conditions required for fish spawning is an effective approach to maintaining the health of riverine ecosystems.

Existing studies on suitable ecological flows during reproduction periods of the fish primarily focus on qualitative determination of suitable flows for the fish reproduction, rather than quantitative determination of a flow variation per unit time from the fish reproduction requirements. Thus, the daily ecological flow variations of the river reaches cannot be described accurately.

### SUMMARY OF PRESENT INVENTION

In view of defects in the prior art, the present disclosure provides a scheduling method for a daily ecological flow variation of a river reach based on an overlap rate of suitable habitats for fish. The present disclosure can effectively solve the above problems.

The present disclosure adopts the following technical solutions:

The present disclosure provides a scheduling method for a daily ecological flow variation of a river reach based on an overlap rate of suitable habitats for fish, including the following steps:
step 1, statistically analyzing historical flows of a studied river reach in a reproduction period of protected fish to determine a maximum baseline flow RFₘₐₓ and a minimum baseline flow RFₘᵢₙ of the studied river reach, and presetting a baseline flow interval ΔRF; and
according to a flow scheduling requirement, presetting a maximum scheduled flow increment QFₘₐₓ and a minimum scheduled flow increment QFₘᵢₙ, and presetting a scheduled flow increment interval ΔQF;
step 2, traversing baseline flows from the maximum baseline flow RFₘₐₓ to the minimum baseline flow RFₘᵢₙ according to the baseline flow interval ΔRF to obtain n baseline flows, each baseline flow being represented as a baseline flow RFᵢ, where, i=1, 2, . . . , n; and
traversing scheduled flow increments from the maximum scheduled flow increment QFₘₐₓ to the minimum scheduled flow increment QFₘᵢₙ according to the scheduled flow increment interval ΔQF to obtain m scheduled flow increments, each scheduled flow increment being represented as a scheduled flow increment QFⱼ, where, j=1, 2, . . . , m;
step 3, for the n baseline flows and the m scheduled flow increments, performing calculation on the baseline flow RFᵢ and the scheduled flow increment QFⱼ to obtain a corresponding overlap rate of suitable habitats for fish, thereby drawing a baseline flow-scheduled flow increment-fish habitat suitability overlap rate distribution map; and
step 4, acquiring a daily mean flow of a current day to serve as a baseline flow, searching the baseline flow-scheduled flow increment-fish habitat suitability overlap rate distribution map to obtain a range of scheduled flow increments with the overlap rate of suitable habitats for fish greater than a preset value, and in combination with the baseline flow and the range of the scheduled flow increments, obtaining a flow scheduling range for a next day.

Preferably, in the step 3, a following method is used to obtain the corresponding overlap rate of suitable habitats for fish for the baseline flow RFᵢ and the scheduled flow increment QFⱼ:
step 3.1, determining a plurality of studied flows according to a range of the baseline flows and a range of the scheduled flow increments for the studied river reach; and for each studied flow, obtaining a corresponding fish reproduction suitability cloud map under the studied flow, specifically:
   step 3.1.1, discretizing the studied river reach into a plurality of grids; and representing each grid as Gridₖ, and obtaining a water depth and a flow velocity of the Gridₖ under the studied flow with a two-dimensional (2D) hydrodynamic numerical model;
   step 3.1.2, based on the water depth and the flow velocity of the Gridₖ under the studied flow, searching a pre-established water depth suitability curve and a pre-established flow velocity suitability curve for the protected fish of the studied river reach, where, the water depth suitability curve is a relation curve between the water depth and a fish reproduction water depth suitability index, and the flow velocity suitability curve is a relation curve between the flow velocity and a fish reproduction flow velocity suitability index, and obtaining a fish reproduction water depth suitability index Dₖ and a fish reproduction flow velocity suitability index Vₖ of the Gridₖ under the studied flow;
   step 3.1.3, obtaining a fish reproduction suitability index CSFₖ of the Gridₖ under the studied flow by:

$$C S {F}_{k} = {V}_{k} \times {D}_{k} \times {C}_{k}$$

where, Cₖ represents a substrate suitability index of the Gridₖ under the studied flow, and ranges from 0 to 1; the substrate suitability index is determined according to a substrate condition of a fish spawning ground acquired on site; when a spawning substrate condition is satisfied, Cₖ is 1; and when the spawning substrate condition is not satisfied, Cₖ is 0;
step 3.1.4, obtaining a fish useable habitat area WUAₖ of the Gridₖ under the studied flow by:

$$W U {A}_{k} = C S {F}_{k} \times {A}_{k}$$

where, Aₖ is a projected area of the Gridₖ on a horizontal plane; and
step 3.1.5, based on the fish useable habitat area WUAₖ of the Gridₖ under the studied flow, obtaining the fish reproduction suitability cloud map under the study flow;
step 3.2, obtaining a scheduled flow F by:

$$F = R {F}_{i} + Q {F}_{j}$$

step 3.3, taking the baseline flow RFᵢ and the scheduled flow F as the studied flow, and searching the fish reproduction suitability cloud map obtained in the step 3.1 to obtain a first fish reproduction suitability cloud map corresponding to the baseline flow RFᵢ and a second fish reproduction suitability cloud map corresponding to the scheduled flow F; and
step 3.4, presetting a fish reproduction suitability threshold, and calculating the overlap rate of suitable habitats for fish between the first fish reproduction suitability cloud map and the second fish reproduction suitability cloud map when a fish reproduction suitability is greater than the fish reproduction suitability threshold.

Preferably, the step 3.4 specifically includes:
binarizing the first fish reproduction suitability cloud map, and labeling a region with the fish reproduction suitability greater than 0.5 as black and other regions as white, thereby obtaining a binarized first fish reproduction suitability cloud map;
binarizing the second fish reproduction suitability cloud map, and labeling a region with the fish reproduction suitability greater than 0.5 as black and other regions as white, thereby obtaining a binarized second fish reproduction suitability cloud map; and
obtaining the overlap rate of suitable habitats for fish between the binarized first fish reproduction suitability cloud map and the binarized second fish reproduction suitability cloud map by:

$${R}_{overlap} = \frac{{A}_{first} ⋂ {A}_{second}}{{A}_{first}}$$

where:
Rₒᵥₑᵣₗₐₚ is the overlap rate of suitable habitats for fish between the binarized first fish reproduction suitability cloud map and the binarized second fish reproduction suitability cloud map;
A_{first} is a suitability distribution area of the binarized first fish reproduction suitability cloud map; and
A_{second} is a suitability distribution area of the binarized second fish reproduction suitability cloud map.

The scheduling method for a daily ecological flow variation of a river reach based on an overlap rate of suitable habitats for fish provided by the present disclosure has the following advantages:

The scheduling method for a daily ecological flow variation of a river reach based on an overlap rate of suitable habitats for fish provided by the present disclosure quantitatively evaluates the overlap rate of the suitable spawning region of the fish in different flow variations under different baseline flows, thereby obtaining a constraint value for the ecological flow variation of the river reach. The method can be applied to different studied river reaches and different spawning fish, with desirable adaptability and strong practicability. It can effectively reduce adverse effects on aquatic ecosystems and fish reproduction of the river reaches during scheduling of hydropower stations, and promotes sustainable high-quality development of the hydropower stations.

### BRIEF DESCRIPTION OF THE DRAWINGS

FIG. 1 is a schematic flowchart of a scheduling method for a daily ecological flow variation of a river reach based on an overlap rate of suitable habitats for fish according to the present disclosure;

FIG. 2 illustrates a topographic map showing a studied river reach according to the present disclosure;

FIG. 3 is a schematic diagram showing a water depth suitability curve according to the present disclosure;

FIG. 4 is a schematic diagram showing a flow velocity suitability curve according to the present disclosure;

FIG. 5 illustrates a fish reproduction suitability cloud map under various studied flows according to the present disclosure;

FIG. 6 illustrates a calculation process of an overlap rate of suitable habitats for fish according to the present disclosure; and

FIG. 7 is a schematic diagram of a baseline flow-scheduled flow increment-fish habitat suitability overlap rate distribution map according to the present disclosure.

### DETAILED DESCRIPTION OF THE EMBODIMENTS

To make the to-be-solved technical problems, the technical solutions, and the beneficial effects of the present disclosure clearer, the present disclosure is described in further detail below with reference to the accompanying drawings and embodiments. It should be understood that the specific examples described herein are merely intended to explain the present disclosure, but not to limit the present disclosure.

A technical problem to be solved by the present disclosure is to provide a quantitative scheduling method for an ecological flow variation based on a fish reproduction suitability requirement of a studied river reach, to overcome a defect that a flow variation per unit time in a fish reproduction period is quantized difficultly. The present disclosure quantitatively evaluates an overlap rate of a suitable spawning region of fish in different flow variations under different baseline flows, thereby obtaining a constraint value for the ecological flow variation of the river reach. The method can be applied to different studied river reaches and different spawning fish, with desirable adaptability and strong practicability. It can effectively reduce adverse effects on aquatic ecosystems and fish reproduction of the river reaches during scheduling of hydropower stations, and promotes sustainable high-quality development of the hydropower stations.

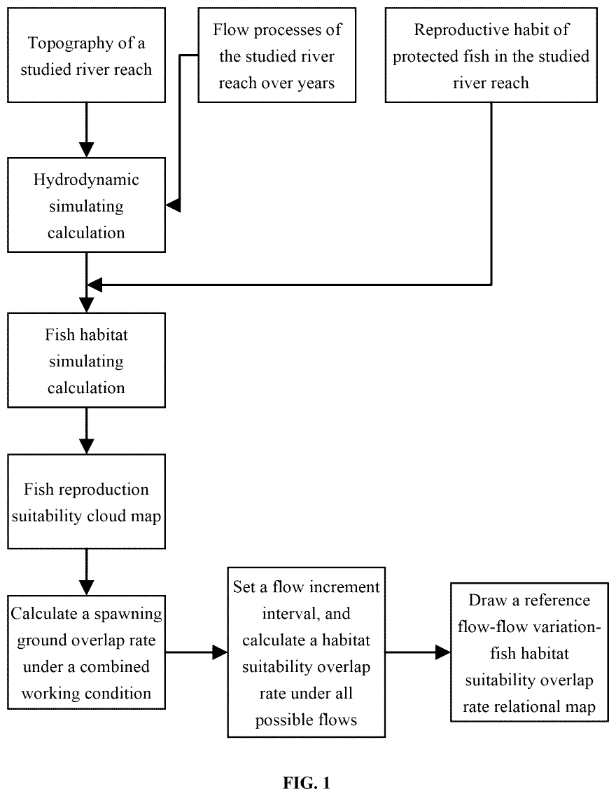

Referring to FIG. 1, a scheduling method for a daily ecological flow variation of a river reach based on an overlap rate of suitable habitats for fish provided by the present disclosure includes the following steps:

In step 1, historical flows of a studied river reach in a reproduction period of protected fish are statistically analyzed to determine a maximum baseline flow RFₘₐₓ and a minimum baseline flow RFₘᵢₙ of the studied river reach, and a baseline flow interval ΔRF is preset.

According to a flow scheduling requirement, a maximum scheduled flow increment QFₘₐₓ and a minimum scheduled flow increment QFₘᵢₙ are preset, and a scheduled flow increment interval ΔQF is preset.

As an example, the reproduction period of the protected fish is from June to July. According to monitoring data on historical flows of the studied river reach from the hydrologic station, distribution probabilities of the flows in the fish reproduction period are counted, and range from 10% to 90%. A maximum and a minimum for baseline flows of the studied river reach are 200 m³/s and 1,400 m³/s, respectively. The baseline flow interval ΔRF is 2.5 m³/s, and there are 481 baseline flows. The scheduled flow increments range from −500 m³/s to 500 m³/s, and the scheduled flow increment interval ΔQF is 10 m³/s.

In step 2, baseline flows are traversed from the maximum baseline flow RFₘₐₓ to the minimum baseline flow RFₘᵢₙ according to the baseline flow interval ΔRF to obtain n baseline flows, each baseline flow being represented as a baseline flow RFᵢ, where, i=1, 2, . . . , n.

Scheduled flow increments are traversed from the maximum scheduled flow increment QFₘₐₓ to the minimum scheduled flow increment QFₘᵢₙ according to the scheduled flow increment interval ΔQF to obtain m scheduled flow increments, each scheduled flow increment being represented as a scheduled flow increment QFⱼ, where, j=1, 2, . . . , m.

In step 3, for the n baseline flows and the m scheduled flow increments, calculation is performed on the baseline flow RFᵢ and the scheduled flow increment QFⱼ to obtain a corresponding overlap rate of suitable habitats for fish, thereby drawing a baseline flow-scheduled flow increment-fish habitat suitability overlap rate distribution map.

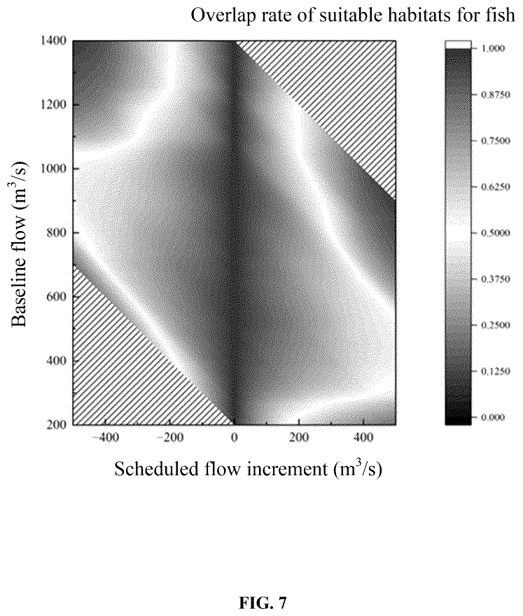

FIG. 7 is a schematic diagram of the baseline flow-scheduled flow increment-fish habitat suitability overlap rate distribution map. In actual application, within a water inflow frequency of 10-90% for the studied river reach over years, an overlap rate of suitable habitats for fish for all possible situations can be obtained. The schematic diagram of the baseline flow-scheduled flow increment-fish habitat suitability overlap rate distribution map is drawn.

In the step 3, a following method is used to obtain the corresponding overlap rate of suitable habitats for fish for the baseline flow RFᵢ and the scheduled flow increment QFⱼ:

In step 3.1, a plurality of studied flows are determined according to a range of the baseline flows and a range of the scheduled flow increments for the studied river reach; and for each studied flow, a corresponding fish reproduction suitability cloud map under the studied flow is obtained. For example, the baseline flows range from 200 m³/s to 1400 m³/s, and the baseline flow interval ΔRF is 2.5 m³/s. The scheduled flow increments range from −500 m³/s to 500 m³/s, and the scheduled flow increment interval ΔQF is 10 m³/s. Therefore, when the baseline flow is 200 m³/s, and the scheduled flow increment is −500 m³/s, the studied flow is 700 m³/s. When the baseline flow is 200 m³/s, and the scheduled flow increment is −490 m³/s, the studied flow is 690 m³/s. In this way, each scheduled flow increment and each baseline flow are traversed, and combined to obtain the plurality of studied flows.

The step 3.1 specifically includes:

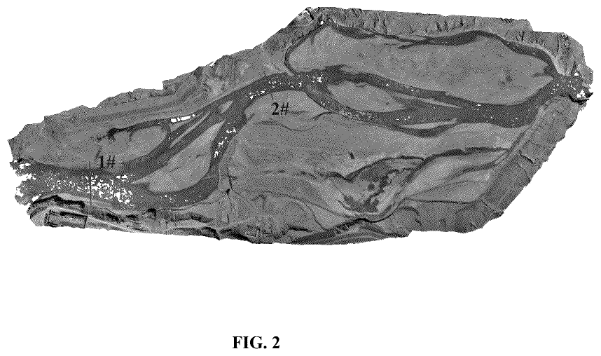

In step 3.1.1, as shown in FIG. 2 that illustrates a topographic map of the studied river reach, the studied river reach is discretized into a plurality of grids. Each grid is represented as Gridₖ, and a water depth and a flow velocity of the Gridₖ under the studied flow are obtained with a 2D hydrodynamic numerical model.

Specifically, topographic features of the studied river reach are acquired, and the 2D hydrodynamic numerical model is constructed. According to the 2D hydrodynamic numerical model, the water depth and the flow velocity of the Gridₖ under the studied flow are obtained. The 2D hydrodynamic numerical model may be an MIKE21 numerical model constructed with a shallow water equation.

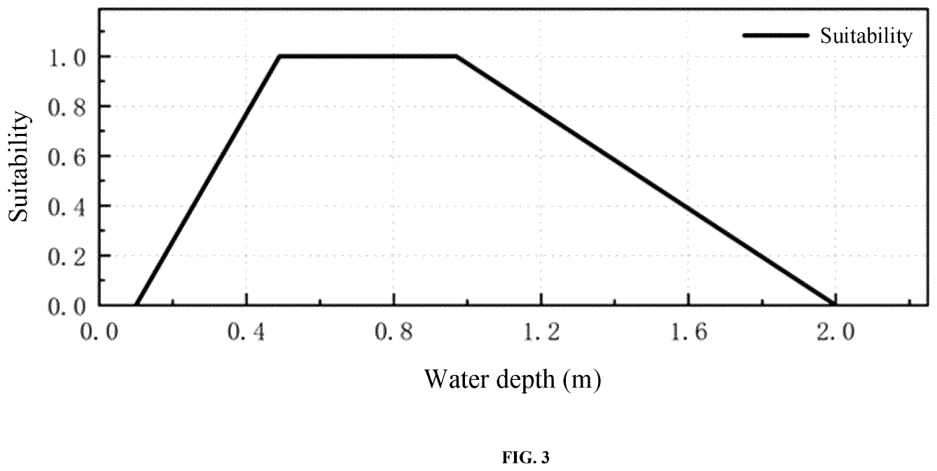

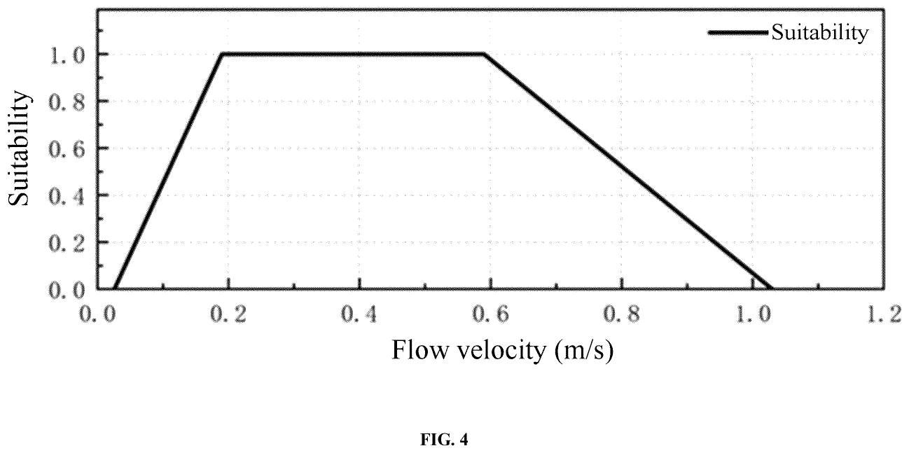

In step 3.1.2, based on the water depth and the flow velocity of the Gridₖ under the studied flow, a pre-established water depth suitability curve and a pre-established flow velocity suitability curve for the protected fish of the studied river reach are searched. The water depth suitability curve is a relation curve between the water depth and a fish reproduction water depth suitability index. FIG. 3 is a schematic diagram of the water depth suitability curve. The flow velocity suitability curve is a relation curve between the flow velocity and a fish reproduction flow velocity suitability index. FIG. 4 is a schematic diagram of the flow velocity suitability curve. A fish reproduction water depth suitability index Dₖ and a fish reproduction flow velocity suitability index Vₖ of the Gridₖ under the studied flow are obtained.

In this step, to obtain the water depth suitability curve and the flow velocity suitability curve for the protected fish of the studied river reach, a fish habitat model is constructed for the studied river reach and analyzed.

In step 3.1.3, a fish reproduction suitability index CSFₖ of the Gridₖ under the studied flow is obtained by:

$$C S {F}_{k} = {V}_{k} \times {D}_{k} \times {C}_{k}$$

where, Cₖ represents a substrate suitability index of the Gridₖ under the studied flow, and ranges from 0 to 1. The substrate suitability index is determined according to a substrate condition of a fish spawning ground acquired on site. When a spawning substrate condition is satisfied, Cₖ is 1. When the spawning substrate condition is not satisfied, Cₖ is 0.

The substrate satisfying spawning requirements of parent fish of indigenous fish in the studied river reach mainly includes pebble (grain size>64 mm), and gravel (4 mm<grain size<64 mm).

Therefore, in the present disclosure, the flow velocity, the water depth and the substrate are considered for the fish reproduction suitability, and the comprehensive suitability index CSFₖ of the Gridₖ under the studied flow is calculated with a product method.

In step 3.1.4, a fish useable habitat area WUAₖ of the Gridₖ under the studied flow is obtained by:

$$W U {A}_{k} = C S {F}_{k} \times {A}_{k}$$

where, Aₖ is a projected area of the Gridₖ on a horizontal plane.

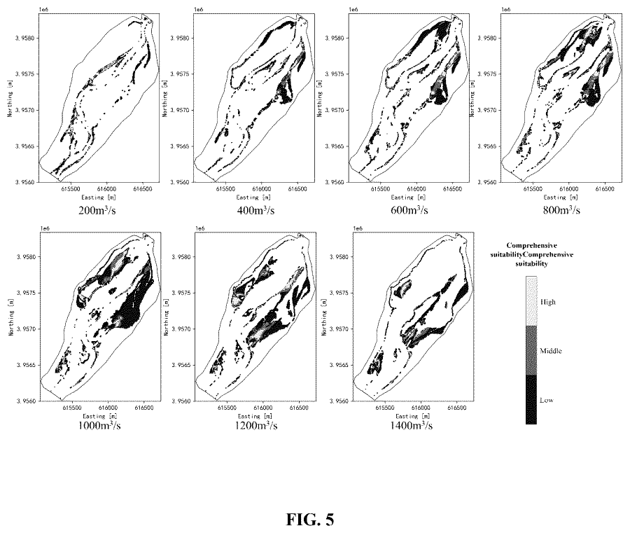

In step 3.1.5, based on the fish useable habitat area WUAₖ of the Gridₖ under the studied flow, the fish reproduction suitability cloud map under the study flow is obtained. FIG. 5 illustrates fish reproduction suitability cloud maps under various studied flows.

In step 3.2, a scheduled flow F is obtained by:

$$F = R {F}_{i} + Q {F}_{j}$$

In step 3.3, the baseline flow RFᵢ and the scheduled flow F are taken as the studied flow, and the fish reproduction suitability cloud map obtained in the step 3.1 is searched to obtain a first fish reproduction suitability cloud map corresponding to the baseline flow RFᵢ and a second fish reproduction suitability cloud map corresponding to the scheduled flow F.

In step 3.4, a fish reproduction suitability threshold is preset, and the overlap rate of suitable habitats for fish between the first fish reproduction suitability cloud map and the second fish reproduction suitability cloud map when a fish reproduction suitability is greater than the fish reproduction suitability threshold is calculated.

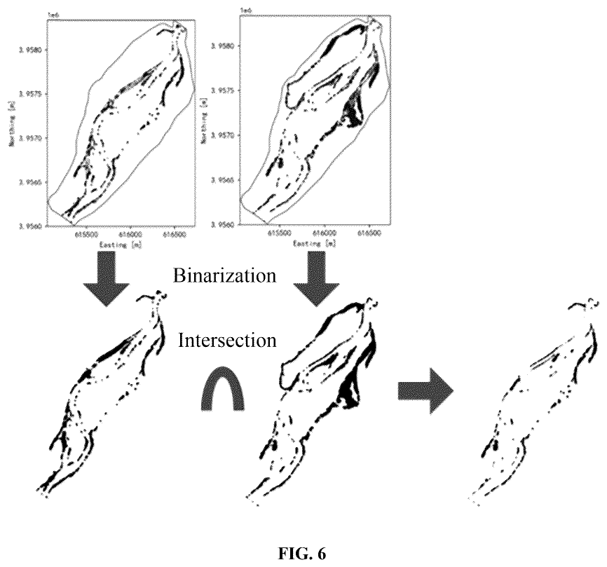

Referring to FIG. 6 that illustrates a calculation process of the overlap rate of suitable habitats for fish, the step 3.4 specifically includes:

The first fish reproduction suitability cloud map is binarized, and a region with the fish reproduction suitability greater than 0.5 is labeled as black and other regions are labeled as white, thereby obtaining a binarized first fish reproduction suitability cloud map.

The second fish reproduction suitability cloud map is binarized, and a region with the fish reproduction suitability greater than 0.5 is labeled as black and other regions are labeled as white, thereby obtaining a binarized second fish reproduction suitability cloud map.

The overlap rate of suitable habitats for fish between the binarized first fish reproduction suitability cloud map and the binarized second fish reproduction suitability cloud map is obtained by:

$${R}_{overlap} = \frac{{A}_{first} ⋂ {A}_{second}}{{A}_{first}}$$

where, Rₒᵥₑᵣₗₐₚ is the overlap rate of suitable habitats for fish between the binarized first fish reproduction suitability cloud map and the binarized second fish reproduction suitability cloud map; A_{first} is a suitability distribution area of the binarized first fish reproduction suitability cloud map; and A_{second} is a suitability distribution area of the binarized second fish reproduction suitability cloud map.

Therefore, in the present disclosure, the overlap rate of suitable habitats for fish is obtained by dividing an overlapping area between the suitability distribution area under the baseline flow RFᵢ and the suitability distribution area under the scheduled flow F by the suitability distribution area under the baseline flow RFᵢ. The obtained Rₒᵥₑᵣₗₐₚ takes the baseline flow RFᵢ as the reference, and the difference between the scheduled flow F and the baseline flow RFᵢ as the flow increment. The Rₒᵥₑᵣₗₐₚ is also called a spawning ground overlap rate in two flow states (the baseline flow RFᵢ and the scheduled flow F).

In step 4, a daily mean flow of a current day is acquired to serve as a baseline flow, the baseline flow-scheduled flow increment-fish habitat suitability overlap rate distribution map is searched to obtain a range of scheduled flow increments with the overlap rate of suitable habitats for fish greater than a preset value, and in combination with the baseline flow and the range of scheduled flow increments, a flow scheduling range in a next day is obtained.

For example, the daily mean flow of the current day is 1,000 m³/s. The baseline flow-scheduled flow increment-fish habitat suitability overlap rate distribution map shown in FIG. 7 is searched to obtain a range of scheduled flow increments with the overlap rate of suitable habitats for fish greater than 0.5, such as 80-100 m³/s. The flow scheduling range in the next day is 1,080 m³/s to 1,100 m³/s.

The scheduling method for a daily ecological flow variation of a river reach based on an overlap rate of suitable habitats for fish provided by the present disclosure first obtains the overlap rate between useable habitat areas under different flows from the fish reproduction requirement, and quantitatively gives suitable increments for daily flows under different baseline flows to serve as the flow scheduled values in the next day. The method can be applied to different studied river reaches and different spawning fish, with desirable adaptability and strong practicability. While fully considering reproductive habits of the fish, the method reduces adverse effects on aquatic ecosystems and fish reproduction of the river reaches during scheduling of hydropower stations, and promotes sustainable high-quality development of the hydropower stations.

The foregoing descriptions are merely preferred implementations of the present disclosure. It should be noted that several improvements and modifications may further be made by a person of ordinary skill in the art without departing from the principle of the present disclosure, and such improvements and modifications should also be deemed as falling within the protection scope of the present disclosure.

What is claimed is:

1. A scheduling method for a daily ecological flow variation of a river reach based on an overlap rate of suitable habitats for fish, comprising the following steps:
step 1, statistically analyzing historical flows of a studied river reach in a reproduction period of protected fish to determine a maximum baseline flow RFₘₐₓ and a minimum baseline flow RFₘᵢₙ of the studied river reach, and presetting a baseline flow interval ΔRF; and
according to a flow scheduling requirement, presetting a maximum scheduled flow increment QFₘₐₓ and a minimum scheduled flow increment QFₘᵢₙ, and presetting a scheduled flow increment interval ΔQF;
step 2, traversing baseline flows from the maximum baseline flow RFₘₐₓ to the minimum baseline flow RFₘᵢₙ according to the baseline flow interval ΔRF to obtain n baseline flows, each baseline flow being represented as a baseline flow RFᵢ, wherein, i=1, 2, . . . , n; and
traversing scheduled flow increments from the maximum scheduled flow increment QFₘₐₓ to the minimum scheduled flow increment QFₘᵢₙ according to the scheduled flow increment interval ΔQF to obtain m scheduled flow increments, each scheduled flow increment being represented as a scheduled flow increment QFⱼ, wherein, j=1, 2, . . . , m;
step 3, for the n baseline flows and the m scheduled flow increments, performing calculation on the baseline flow RFᵢ and the scheduled flow increment QFⱼ to obtain a corresponding overlap rate of suitable habitats for fish, thereby drawing a baseline flow-scheduled flow increment-fish habitat suitability overlap rate distribution map; and
step 4, acquiring a daily mean flow of a current day to serve as a baseline flow, searching the baseline flow-scheduled flow increment-fish habitat suitability overlap rate distribution map to obtain a range of scheduled flow increments with the overlap rate of suitable habitats for fish greater than a preset value, and in combination with the baseline flow and the range of the scheduled flow increments, obtaining a flow scheduling range for a next day.

2. The scheduling method according to claim 1, wherein in the step 3, a following method is used to obtain the corresponding overlap rate of suitable habitats for fish for the baseline flow RFᵢ and the scheduled flow increment QFⱼ:
step 3.1, determining a plurality of studied flows according to a range of the baseline flows and a range of the scheduled flow increments for the studied river reach; and for each studied flow, obtaining a corresponding fish reproduction suitability cloud map under the studied flow, specifically:
step 3.1.1, discretizing the studied river reach into a plurality of grids; and representing each grid as Gridₖ, and obtaining a water depth and a flow velocity of the Gridₖ under the studied flow with a two-dimensional (2D) hydrodynamic numerical model;
step 3.1.2, based on the water depth and the flow velocity of the Gridₖ under the studied flow, searching a pre-established water depth suitability curve and a pre-established flow velocity suitability curve for the protected fish of the studied river reach, wherein, the water depth suitability curve is a relation curve between the water depth and a fish reproduction water depth suitability index, and the flow velocity suitability curve is a relation curve between the flow velocity and a fish reproduction flow velocity suitability index, and obtaining a fish reproduction water depth suitability index Dₖ and a fish reproduction flow velocity suitability index Vₖ of the Gridₖ under the studied flow;
step 3.1.3, obtaining a fish reproduction suitability index CSFₖ of the Gridₖ under the studied flow by:
$$C S {F}_{k} = {V}_{k} \times {D}_{k} \times {C}_{k}$$
wherein, Cₖ represents a substrate suitability index of the Gridₖ under the studied flow, and ranges from 0 to 1; the substrate suitability index is determined according to a substrate condition of a fish spawning ground acquired on site; when a spawning substrate condition is satisfied, Cₖ is 1; and when the spawning substrate condition is not satisfied, Cₖ is 0;
step 3.1.4, obtaining a fish useable habitat area WUAₖ of the Gridₖ under the studied flow by:
$$W U {A}_{k} = C S {F}_{k} \times {A}_{k}$$
wherein, Aₖ is a projected area of the Gridₖ on a horizontal plane; and
step 3.1.5, based on the fish useable habitat area WUAₖ of the Grid under the studied flow, obtaining the fish reproduction suitability cloud map under the study flow;
step 3.2, obtaining a scheduled flow F by:
$$F = R {F}_{i} + Q {F}_{j}$$
step 3.3, taking the baseline flow RFᵢ and the scheduled flow F as the studied flow, and searching the fish reproduction suitability cloud map obtained in the step 3.1 to obtain a first fish reproduction suitability cloud map corresponding to the baseline flow RFᵢ and a second fish reproduction suitability cloud map corresponding to the scheduled flow F; and
step 3.4, presetting a fish reproduction suitability threshold, and calculating the overlap rate of suitable habitats for fish between the first fish reproduction suitability cloud map and the second fish reproduction suitability cloud map when a fish reproduction suitability is greater than the fish reproduction suitability threshold.

3. The scheduling method according to claim 2, wherein the step 3.4 specifically comprises:
binarizing the first fish reproduction suitability cloud map, and labeling a region with the fish reproduction suitability greater than 0.5 as black and other regions as white, thereby obtaining a binarized first fish reproduction suitability cloud map;
binarizing the second fish reproduction suitability cloud map, and labeling a region with the fish reproduction suitability greater than 0.5 as black and other regions as white, thereby obtaining a binarized second fish reproduction suitability cloud map; and
obtaining the overlap rate of suitable habitats for fish between the binarized first fish reproduction suitability cloud map and the binarized second fish reproduction suitability cloud map by:
$${R}_{overlap} = \frac{{A}_{first} ⋂ {A}_{second}}{{A}_{first}}$$
wherein:
Rₒᵥₑᵣₗₐₚ is the overlap rate of suitable habitats for fish between the binarized first fish reproduction suitability cloud map and the binarized second fish reproduction suitability cloud map;
A_{first} is a suitability distribution area of the binarized first fish reproduction suitability cloud map; and
A_{second} is a suitability distribution area of the binarized second fish reproduction suitability cloud map.
